(19) United States
(12) Patent Application Publication
(10) Pub. No.: US 2024/0316896 A1
(43) Pub. Date: Sep. 26, 2024

(54) DISPLAY APPARATUS

(71) Applicant: Samsung Display Co., Ltd., Yongin-Si (KR)

(72) Inventors: Hirotsugu Kishimoto, Yongin-si (KR); Yongkwan Kim, Yongin-si (KR); Hyunjae Na, Yongin-si (KR); Sungguk An, Yongin-si (KR); Seokwon Jang, Yongin-si (KR); Chulho Jeong, Yongin-si (KR)

(21) Appl. No.: 18/600,842

(22) Filed: Mar. 11, 2024

(30) Foreign Application Priority Data
Mar. 24, 2023 (KR) 10-2023-0039057
Apr. 24, 2023 (KR) 10-2023-0053576

(51) Int. Cl. B32B 5/12; G06F 3/041; H05K 5/02

(52) U.S. Cl. CPC B32B 5/12; G06F 3/0412; H05K 5/02; B32B 2260/023; B32B 2260/046; B32B 2264/108; B32B 2307/54; B32B 2307/558; B32B 2307/718; B32B 2457/20

(57) ABSTRACT

A display apparatus includes a display module, and a plate arranged below the display module and including pitch-based carbon fiber.

### CROSS-REFERENCE TO RELATED APPLICATION

This application is based on and claims priority under 35 U.S.C. § 119 to Korean Patent Application Nos. 10-2023-0039057, filed on Mar. 24, 2023, and 10-2023-0053576, filed on Apr. 24, 2023, in the Korean Intellectual Property Office, the disclosures of which are incorporated by reference herein in their entirety.

### BACKGROUND

### 1. Field

One or more embodiments relate to a display apparatus.

### 2. Description of the Related Art

Recently, display apparatuses are being used in a greater variety of ways. In addition, display apparatuses have become thinner and lighter in weight, and thus, their range of use has widened.

While expanding the area of display apparatuses occupied by an active area, various functions that may be connected or linked to display apparatuses have been added. As a way of adding various functions while expanding the display area, research on display apparatuses having an area inside the active area for adding various functions other than image display is being conducted.

### SUMMARY

One or more embodiments include a display apparatus with improved resistance to impact.

Additional aspects will be set forth in part in the description which follows and, in part, will be apparent from the description, or may be learned by practice of the presented embodiments of the disclosure.

According to one or more embodiments, a display apparatus includes a display module, and a plate arranged below the display module and including pitch-based carbon fiber.

The plate may further include polyacrylonitrile (PAN)-based carbon fiber.

The plate may include a plurality of layers.

An outermost layer of the plate may include PAN-based carbon fiber, and an inner layer may include pitch-based carbon fiber.

The plate may include a first layer, a second layer, and a third layer that are sequentially stacked on one another.

The first layer and the third layer may include the same carbon fiber.

The first layer and the second layer may include different carbon fibers.

The first layer and the third layer may include PAN-based carbon fiber.

The second layer may include pitch-based carbon fiber.

A fiber area weight (FAW) of the first layer may be greater than or equal to 20 g/m² and less than or equal to 30 g/m².

A FAW of the third layer may be greater than or equal to 20 g/m² and less than or equal to 30 g/m².

A FAW of the second layer may be greater than or equal to 50 g/m² and less than or equal to 150 g/m².

A longitudinal direction of the carbon fiber included in the first layer may be parallel to a first direction.

A longitudinal direction of the carbon fiber included in the second layer may be parallel to a second direction crossing the first direction.

A longitudinal direction of the carbon fiber included in the third layer may be parallel to the first direction.

The display apparatus may further include a digitizer arranged under the plate.

According to one or more embodiments, a display apparatus includes a display module including a first area, a second area, and a folding area, and being foldable with respect to a folding axis, and a plate arranged below the display module and including pitch-based carbon fiber.

The second area may include a 2-1^{st} area and a 2-2^{nd} area.

The folding area may be disposed between the 2-1^{st} area and the 2-2^{nd} area.

The plate may further include polyacrylonitrile (PAN)-based carbon fiber.

The folding axis may extend in a first direction.

The plate may include a first layer, a second layer, and a third layer that are sequentially stacked on one another.

The first layer and the third layer may include PAN-based carbon fiber.

The second layer may include the pitch-based carbon fiber.

A fiber area weight (FAW) of each of the first layer and the third layer may be greater than or equal to 20 g/m² and less than or equal to 30 g/m².

A FAW of the second layer may be greater than or equal to 50 g/m² and less than or equal to 150 g/m².

A longitudinal direction of a carbon fiber included in the first layer may be parallel to the first direction.

A longitudinal direction of a carbon fiber included in the second layer may be parallel to a second direction crossing the first direction.

A longitudinal direction of a carbon fiber included in the third layer may be parallel to the first direction.

The display apparatus may further include a digitizer arranged under the plate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is an exploded perspective view of a display apparatus according to an embodiment;

FIG. 3 is a block diagram of a display apparatus according to an embodiment;

FIG. 4 is a schematic perspective view of a display apparatus according to an embodiment;

FIG. 5 is a schematic cross-sectional view of a display apparatus according to an embodiment;

FIG. 6 is a schematic cross-sectional view of a display module of a display apparatus according to an embodiment;

FIG. 7 is a schematic cross-sectional view of a plate according to an embodiment;

FIG. 8 is a schematic diagram of a method of manufacturing polyacrylonitrile (PAN)-based carbon fiber;

FIG. 9 is a schematic diagram of a method of manufacturing pitch-based carbon fiber;

FIG. 10 is a schematic diagram of a process of manufacturing a plate, according to an embodiment; and

FIGS. 11 and 12 are diagrams showing evaluation results of vibration damping characteristics of carbon fiber reinforced plastic including PAN-based carbon fiber and carbon fiber reinforced plastic including pitch-based carbon fiber, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

As used herein, the expression “A and/or B” refers to A, B, or A and B. In addition, the expression “at least one of A and B” refers to A, B, or A and B.

As used herein, the description that a wire “extends in a first direction or a second direction” covers not only a case where the wire extends in a straight line but also a case where the wire extends in a zigzag or curve in the first or second direction.

As used herein, the phrase “in a plan view” indicates that a portion of a target object is seen from above, and the phrase “in a cross-sectional view” indicates that a portion of a target object is vertically cut and the cross-section is viewed from the side. As used herein, the term “overlap” covers overlapping “in a plan view” and “in a cross-sectional view.”

One or more embodiments will be described below in more detail with reference to the accompanying drawings. Those elements that are the same or are in correspondence with each other are rendered the same reference numeral regardless of the figure number.

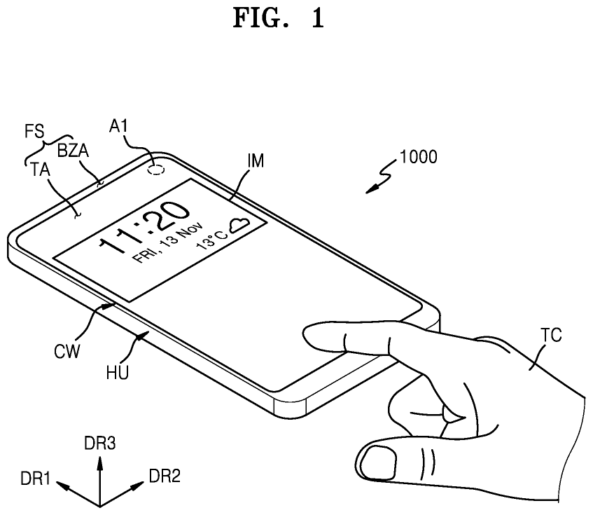

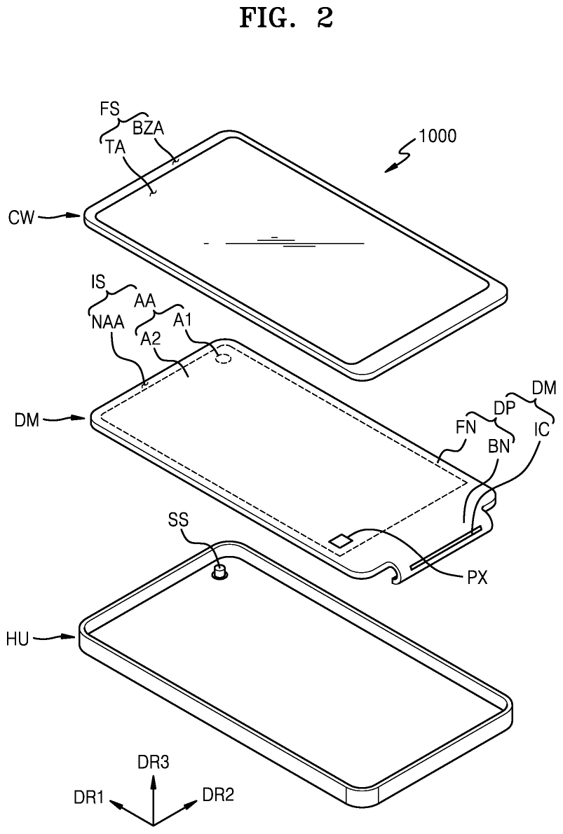

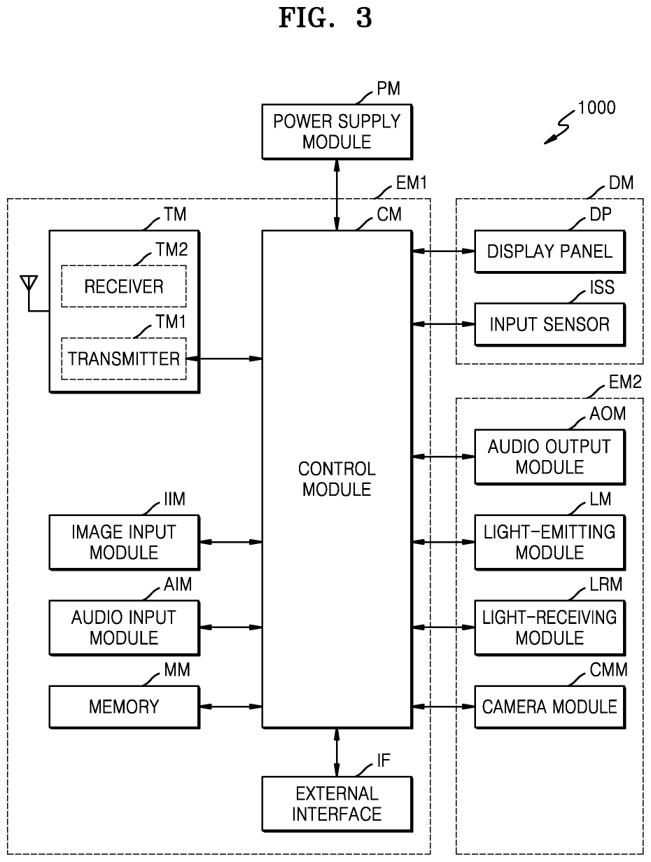

FIG. 1 is a schematic perspective view of a display apparatus 1000 according to an embodiment. FIG. 2 is an exploded perspective view of the display apparatus 1000 according to an embodiment. FIG. 3 is a block diagram of the display apparatus 1000 according to an embodiment.

The display apparatus 1000 according to an embodiment is an apparatus that displays a moving image or a still image, and may be used as the display screen of not only portable display devices, such as a mobile phone, a smartphone, a tablet personal computer (PC), a mobile communication terminal, an electronic notebook, an e-book, a portable multimedia player (PMP), a navigation device, and an ultra-mobile PC (UMPC), but also various products, such as a television, a notebook computer, a monitor, a billboard, and an Internet of things (IoT) device. In addition, the display apparatus 1000 according to an embodiment may be used in wearable devices, such as a smartwatch, a watch phone, a glasses-type display, and a head-mounted display (HMD). In addition, the display apparatus 1000 according to an embodiment may be used as a car's instrument panel, a center information display (CID) placed on a car's center fascia or dashboard, a room mirror display replacing a car's side mirror, or a display placed on the back of a front seat as entertainment for a car's rear seat. FIG. 1 shows the display apparatus 1000 being used as a smartphone for convenience of description.

Referring to FIGS. 1 to 3, the display apparatus 1000 may display an image IM in a third direction DR3 on a display surface that is parallel to each of a first direction DR1 and a second direction DR2. The display surface on which the image IM is displayed may correspond to a front surface of the display apparatus 1000 and may correspond to a front surface FS of a cover window CW.

Hereinafter, the same reference numeral will be used for the display surface and the front surface of the display apparatus 1000 and the front surface of the cover window CW. The image IM may include a still image as well as a moving image. In FIG. 1, a clock is shown as an embodiment of the image IM.

In the present embodiment, a front surface (or a top surface) and a rear surface (or a bottom surface) of each member are defined based on a direction in which the image IM is displayed. The front surface and the rear surface may be opposite to each other in the third direction DR3, and a normal direction of each of the front surface and the rear surface may be parallel to the third direction DR3. A distance between the front and rear surfaces in the third direction DR3 may correspond to a thickness of a display module DM in the third direction DR3.

The display apparatus 1000 according to an embodiment may detect a user input TC applied from the outside. The user input TC may include various forms of external inputs, such as a part of a user's body, light, heat, or pressure. In an embodiment, a user's hand applied to the front surface is shown as the user input TC. However, one or more embodiments are not limited thereto. The user input TC may be provided in various forms. In addition, the display apparatus 1000 may detect the user input TC applied to a side surface or a rear surface of the display apparatus 1000 depending on a structure of the display apparatus 1000.

In an embodiment, a first area A1 may be defined within a light transmission area TA. The first area A1 may be an area at least partially overlapping an electronic module SS. FIG. 1 shows the first area A1 having a circular shape on an upper right side of the display apparatus 1000, but one or more embodiments are not limited thereto. The first area A1 may vary in number and shape according to the number and shape of the electronic module SS.

The display apparatus 1000 may receive an external signal required for the electronic module SS through the first area A1 or may provide a signal output from the electronic module SS to the outside through the first area A1. In an embodiment, the first area A1 may overlap the light transmission area TA, thereby reducing the area of a bezel area BZA.

The display apparatus 1000 may include the cover window CW, a housing HU, the display module DM, and the electronic module SS. In an embodiment, the cover window CW and the housing HU may be coupled to each other to form an exterior of the display apparatus 1000.

The cover window CW may include an insulating panel. For example, the cover window CW may include glass, plastic, or a combination thereof.

The front surface FS of the cover window CW may define the front surface of the display apparatus 1000. The light transmission area TA may be an optically transparent area. For example, the light transmission area TA may be an area having a visible light transmittance of about 90% or greater.

The bezel area BZA may define a shape of the light transmission area TA. The bezel area BZA may be disposed adjacent to the light transmission area TA and may surround the light transmission area TA. The bezel area BZA may be an area having a relatively low light transmittance compared to the light transmission area TA. The bezel area BZA may include an opaque material that blocks light. The bezel area BZA may have a certain color. The bezel area BZA may be defined by a bezel layer provided separately from a transparent substrate defining the light transmission area TA or may be defined by an ink layer formed by being inserted into or colored on the transparent substrate.

The display module DM may include a display panel DP for displaying the image IM, an input sensor ISS (refer to FIG. 3) for detecting the external input TC, and a driving circuit IC. The display module DM may include a front surface IS including an active area AA and a peripheral area NAA. The active area AA may be an area that is activated according to an electrical signal.

In an embodiment, the active area AA may be an area where the image IM is displayed and may also be an area where the external input TC is detected. The active area AA may be an area where a plurality of pixels described below are arranged.

The light transmission area TA may at least partially overlap the active area AA. For example, the light transmission area TA may overlap an entire surface of the active area AA or may overlap at least a portion of the active area AA. Accordingly, a user may see the image IM or provide the external input TC through the light transmission area TA. However, one or more embodiments are not limited thereto. For example, an area where the image IM is displayed and an area where the external input TC is detected may be separated from each other in the active area AA.

The peripheral area NAA may at least partially overlap the bezel area BZA. The peripheral area NAA may be an area covered by the bezel area BZA. The peripheral area NAA may be disposed adjacent to the active area AA. The peripheral area NAA may surround the active area AA. The peripheral area NAA may be an area where the image IM is not displayed. A driving circuit or a driving line configured to drive the active area AA may be arranged in the peripheral area NAA.

In an embodiment, the display module DM may be assembled in a flat state in which the active area AA and the peripheral area NAA face the cover window CW. However, one or more embodiments are not limited thereto. A portion of the peripheral area NAA of the display module DM may be bent. In this regard, a portion of the peripheral area NAA may face the rear surface of the display apparatus 1000, thereby reducing the bezel area BZA shown on the front surface of the display apparatus 1000. Alternatively, the display module DM may be assembled in a state where a portion of the active area AA is bent. Alternatively, the peripheral area NAA may be omitted from the display module DM.

The active area AA may include the first area A1 and a second area A2. The first area A1 may have a relatively high light transmittance compared to the second area A2. In addition, the first area A1 may have a relatively small area compared to the second area A2. The first area A1 may be defined as an area of the display module DM that overlaps an area where the electronic module SS is arranged inside the housing HU. In an embodiment, the first area A1 is shown as having a circular shape, but one or more embodiments are not limited thereto. The first area A1 may have a variety of shapes, such as a polygonal shape, an oval shape, a shape with at least one curved line, etc.

The second area A2 may be disposed adjacent to the first area A1. In an embodiment, the second area A2 may surround the entire first area A1. However, one or more embodiments are not limited thereto. The second area A2 may partially surround the first area A1.

Referring to FIG. 3, the display module DM may include the display panel DP and the input sensor ISS. The display panel DP may be an element configured to generate the image IM. The image IM generated by the display panel DP may be displayed on the display surface IS and visible to a user through the light transmission area TA.

The input sensor ISS may detect the external input TC applied from the outside. The input sensor ISS may detect the external input TC provided to the cover window CW.

Referring to FIG. 2 again, the display panel DP may include a flat portion FN and a bending portion BN. The flat portion FN may be assembled to be substantially parallel to a plane defined by the first direction DR1 and the second direction DR2. The active area AA may be provided in the flat portion FN.

The bending portion BN may extend from the flat portion FN, and at least a portion of the bending portion BN may be bent. The bending portion BN may be assembled to be bent from the flat portion FN and disposed on a rear side of the flat portion FN. Because the bending portion BN overlaps the flat portion FN in a plan view when being assembled, the bezel area BZA of the display apparatus 1000 may be reduced. However, one or more embodiments are not limited thereto. For example, the bending portion BN may be omitted.

The driving circuit IC may be mounted on the bending portion BN. The driving circuit IC may be provided in the form of a chip. However, one or more embodiments are not limited thereto. The driving circuit IC may be provided on a separate circuit board and electrically connected to the electronic panel EP through a flexible film or the like.

The driving circuit IC may be electrically connected to the active area AA to provide an electrical signal to the active area AA. For example, the driving circuit IC may include a data driving circuit which may be configured to provide data signals to pixels PX that are arranged in the active area AA. Alternatively, the driving circuit IC may include a touch driving circuit which may be electrically connected to the input sensor ISS arranged in the active area AA. The driving circuit IC may include any of a variety of circuits other than the above-described circuits or may be designed to provide a variety of electrical signals to the active area AA.

The display apparatus 1000 may further include a main circuit board (not shown) electrically connected to the display panel DP and the driving circuit IC. The main circuit board may include various driving circuits configured to drive the display panel DP or a connector for power supply. The main circuit board may be a rigid printed circuit board (PCB) or a flexible circuit board.

The electronic module SS may be disposed under the display module DM. The electronic module SS may receive an external input transmitted through the first area A1 or may output a signal through the first area A1. In an embodiment, because the first area A1 having a relatively high transmittance is provided in the active area AA, the electronic module SS may overlap the active area AA, and accordingly, the area (or size) of the bezel area BZA may be reduced.

Referring to FIG. 3, the display apparatus 1000 may include the display module DM, a power supply module PM, a first electronic module EM1, and a second electronic module EM2. The display module DM, the power supply module PM, the first electronic module EM1, and the second electronic module EM2 may be electrically connected to one another. In FIG. 3, the display panel DP and the input sensor ISS from among elements of the display module DM are shown as an example.

The power supply module PM may supply power required for the overall operation of the display apparatus 1000. The power supply module PM may include a conventional battery module.

The first electronic module EM1 and the second electronic module EM2 may include various functional modules for operating the display apparatus 1000. The first electronic module EM1 may be directly mounted on a motherboard electrically connected to the display panel DP, or may be mounted on a separate board and electrically connected to the motherboard through a connector (not shown) or the like.

The first electronic module EM1 may include a control module CM, a wireless communication module TM, an image input module IIM, an audio input module AIM, a memory MM, and an external interface IF. Some of the modules may not be mounted on the motherboard but may be electrically connected to the motherboard through a flexible circuit board.

The control module CM may control the overall operation of the display apparatus 1000. The control module CM may be a microprocessor. For example, the control module CM may activate or deactivate the display panel DP. The control module CM may control other modules, such as the image input module IIM or the audio input module AIM in response to a touch signal received from the display panel DP.

The wireless communication module TM may transmit/receive a wireless signal to/from another terminal by using Bluetooth or Wi-Fi connections. The wireless communication module TM may transmit/receive a voice signal by using a general communication line. The wireless communication module TM includes a transmitter TM1 for modulating and transmitting a signal to be transmitted and a receiver TM2 for demodulating a received signal.

The image input module IIM may process an image signal and convert the image signal into image data that is able to be displayed on the display module DM. The audio input module AIM may receive an external audio signal through a microphone in a recording mode or a voice recognition mode and convert the external audio signal into electrical voice data.

The external interface IF may serve as an interface connected to an external charger, a wired/wireless data port, or a card socket (e.g., a memory card, a SIM/UIM card).

The second electronic module EM2 may include an audio output module AOM, a light-emitting module LM, a light-receiving module LRM, and a camera module CMM. The second electronic module EM2 may be directly mounted on the motherboard, may be mounted on a separate board and electrically connected to the display module DM through a connector (not shown) or the like, or may be electrically connected to the first electronic module EM1.

The audio output module AOM may convert audio data received from the wireless communication module TM or audio data stored in the memory MM and output the converted audio data externally.

The light-emitting module LM may generate and output light. The light-emitting module LM may output infrared rays. For example, the light-emitting module LM may include a light-emitting diode (LED) element. For example, the light-receiving module LRM may detect infrared rays. The light-receiving module LRM may be activated when infrared rays of a certain level or higher are detected. The light-receiving module LRM may include a complementary metal-oxide-semiconductor (CMOS) sensor. Infrared light generated by the light-emitting module LM may be output and then be reflected by an external object (e.g., a user's finger or face), and the reflected infrared light may be incident on the light-receiving module LRM. The camera module CMM may capture an external image.

In an embodiment, the electronic module SS may include at least one of the elements of the first electronic module EM1 and the second electronic module EM2. For example, the electronic module SS may include at least one of a camera, a speaker, an optical detection sensor, or a thermal detection sensor. The electronic module SS may detect an external object received through the front surface IS or may provide a sound signal, such as voice, to the outside through the front surface IS. In addition, the electronic module SS may include a plurality of elements and is not limited to a particular embodiment.

Referring to FIG. 2 again, the housing HU may be coupled to the cover window CW. The cover window CW may be disposed on the front surface FS of the housing HU. The housing HU may include a rear surface and a side surface. The cover window CW may be disposed on the front surface of the housing HU. That is, the cover window CW may be disposed on the housing HU. The housing HU may be coupled to the cover window CW to provide a certain accommodation space. The display module DM and the electronic module SS may be accommodated in the certain accommodation space provided between the housing HU and the cover window CW.

The housing HU may include a material having relatively high rigidity. For example, the housing HU may include glass, plastic, or metal, or may include a plurality of frames and/or plates made of a combination thereof. The housing HU may stably protect elements of the display apparatus 1000 accommodated in an internal space from external impact.

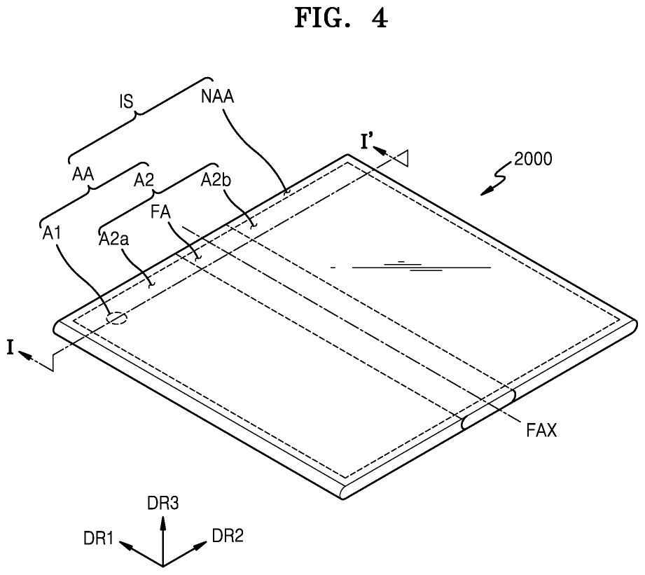

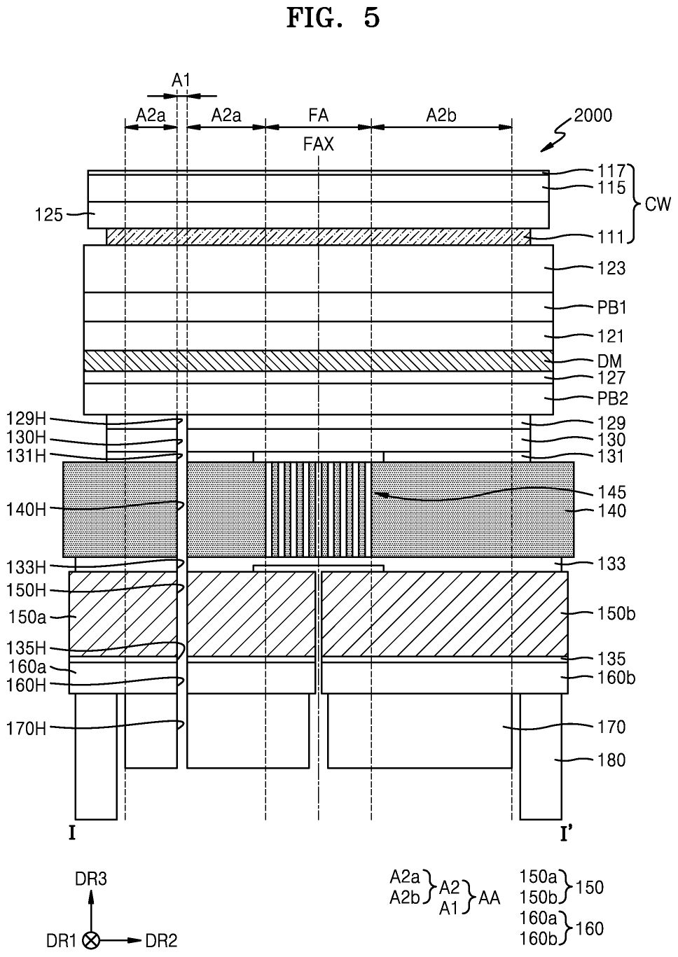

FIG. 4 is a schematic perspective view of a display apparatus 2000 according to an embodiment. FIG. 5 is a schematic cross-sectional view of the display apparatus 2000 according to an embodiment. FIG. 4 is a diagram showing a case where the display apparatus 2000 is foldable. FIG. 5 is a diagram for describing a stacking relationship between members constituting the display apparatus 2000, and, in FIG. 5, members constituting the display apparatus 2000 are simply shown for convenience of description and illustration.

Referring to FIG. 4, in an embodiment, the display apparatus 2000 may be a foldable display apparatus. The display apparatus 2000 may be folded with respect to (or about) a folding axis FAX. In an embodiment, the display surface IS of the display apparatus 2000 may be on an outer side or an inner side of the display apparatus 2000. The display apparatus 2000 may include a housing, a display module, and a cover window.

In an embodiment, the display apparatus 2000 may include the active area AA and the peripheral area NAA. The active area AA may be an area where an image is displayed and may also be an area where an external input is detected. The active area AA may be an area where a plurality of pixels described below are arranged.

The active area AA may include the first area A1 and the second area A2. In addition, the second area A2 may include a 2-1^{st} area A2a, a 2-2^{nd} area A2b, and a folding area FA. The 2-1^{st} area A2a and the 2-2^{nd} area A2b may be respectively positioned on a left side and a right side with respect to (or based on) the folding axis FAX, and the folding area FA may be disposed between the 2-1^{st} area A2a and the 2-2^{nd} area A2b. However, one or more embodiments are not limited thereto.

FIG. 4 shows the first area A1 having a circular shape on an upper left side of the display apparatus 2000, but one or more embodiments are not limited thereto. The first area A1 may vary in number and shape according to the number and shape of the electronic module SS (refer to FIG. 3). In addition, a position of the first area A1 may also vary, for example, the first area A1 may be disposed on an upper right side of the display apparatus 2000.

In addition, FIG. 4 shows the first area A1 being at least partially surrounded by the 2-1^{st} area A2a, but one or more embodiments are not limited thereto. For example, the first area A1 may be at least partially surrounded by the 2-2^{nd} area A2b. That is, the first area A1 may be disposed on an upper right side of the display apparatus 2000.

The folding axis FAX may extend in the first direction DR1. In this case, the display apparatus 2000 may be folded along the second direction DR2 crossing the first direction DR1. When the display apparatus 2000 is folded about the folding axis FAX, a size of the display apparatus 2000 may be reduced, and thus, portability of the display apparatus 2000 may be improved. In addition, when the display apparatus 2000 is completely unfolded, the active area AA may display an image while forming a flat surface, thereby implementing a large screen.

Referring to FIG. 5, in an embodiment, the display apparatus 2000 may include the cover window CW, a first protection member PB1, the display module DM, a second protection member PB2, a support member 130, a plate 140, a digitizer 150, a heat dissipation member 160, a cushion layer 170, and a waterproof member 180.

The first protection member PB1 may be disposed over the display module DM. The first protection member PB1 may be adhered to the display module DM through a first adhesive layer 121. In this regard, the first adhesive layer 121 may include a pressure-sensitive adhesive (PSA). However, one or more embodiments are not limited thereto. The first adhesive layer 121 may include an optically clear adhesive (OCA).

The first protection member PB1 may be positioned over the display module DM to protect the display module DM from external impact. The first protection member PB1 may include polymer resin. For example, the first protection member PB1 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, one or more embodiments are not limited thereto. The first protection member PB1 may include a material, such as glass or quartz.

The cover window CW may be disposed over the first protection member PB1. The cover window CW may be adhered to the first protection member PB1 through a second adhesive layer 123. However, one or more embodiments are not limited thereto. Another element may be further provided between the first protection member PB1 and the cover window CW.

The cover window CW may include a window 111, a window protection member 115, and a hard coating layer 117. The window 111 may include Ultra Thin Glass (UTG™). However, one or more embodiments are not limited thereto. The window 111 may include polymer resin.

The window protection member 115 may be disposed over the window 111. The window protection member 115 may be adhered to the window 111 through a third adhesive layer 125. The window protection member 115 may protect the window 111 from external impact and may prevent or reduce scratches on a top surface of the window 111. The window protection member 115 may include polymer resin. However, one or more embodiments are not limited thereto. The window protection member 115 may include an inorganic material.

The hard coating layer 117 may be disposed on the window protection member 115. The hard coating layer 117 may include an organic material, such as polymer resin. However, one or more embodiments are not limited thereto. The hard coating layer 117 may include an inorganic material.

The hard coating layer 117 may be an outermost layer of the cover window CW. In this regard, the outermost layer of the cover window CW may refer to an outermost layer of the display apparatus 2000. The outermost layer of the cover window CW is a layer that a user directly touches, and when the outermost layer of the cover window CW includes Ultra Thin Glass (UTG™) or the window protection member 115, a user's touch feeling may deteriorate. Because the outermost layer of the cover window CW is the hard coating layer 117, a smooth and soft touch feeling may be provided to a user.

Although not shown, an opaque layer may be provided between the window protection member 115 and the third adhesive layer 125. The opaque layer may be provided at a portion of the window protection member 115. The opaque layer may include an opaque material so that wires, circuits, etc. of the display panel DP are not identified from the outside. A portion where the opaque layer is arranged may be the bezel area BZA.

The second protection member PB2 may be disposed under the display module DM. The second protection member PB2 may be adhered to the display module DM through a fourth adhesive layer 127. The second protection member PB2 may be disposed under the display module DM to support the display module DM and protect the display module DM from external impact. The second protection member PB2 may include polymer resin, such as polyethylene terephthalate or polyimide.

The support member 130 may be disposed under the second protection member PB2. The support member 130 may be adhered to the second protection member PB2 through a fifth adhesive layer 129. The support member 130 may be positioned below the display module DM to support the display module DM. The support member 130 may include polymer resin, such as polyethylene terephthalate or polyimide. The support member 130 may be omitted.

The plate 140 may be disposed under the support member 130. The plate 140 may be adhered to the support member 130 through a sixth adhesive layer 131. In this regard, the sixth adhesive layer 131 may not be provided at a portion corresponding to the folding area FA.

The plate 140 may be positioned below the display module DM to support the display module DM. In addition, the plate 140 may be positioned over the digitizer 150 described below.

In an embodiment, the plate 140 may include a folding structure 145. When the display apparatus 2000 is folded, the folding structure 145 may have a variable shape or a variable length. For example, the folding structure 145 may include a pattern portion with openings, a shape of protrusions and depressions, or links rotatably connected to each other. However, one or more embodiments are not limited thereto.

In an embodiment, when the display apparatus 2000 is folded, the folding structure 145 may be folded with respect to (or about) the folding axis FAX. In an embodiment, both sides of the folding structure 145 may be symmetrical to each other with respect to (or based on) the folding axis FAX. In an embodiment, the plate 140 except the folding structure 145 may have a flat top surface.

The digitizer 150 may be disposed under the plate 140. The digitizer 150 may be adhered to the plate 140 through a seventh adhesive layer 133. The seventh adhesive layer 133 may be positioned under the plate 140 to prevent or reduce foreign materials from entering the folding structure 145 of the plate 140. At least a portion of the seventh adhesive layer 133 overlapping the folding area FA may be removed. However, the disclosure is not limited thereto. The seventh adhesive layer 133 may not be provided at a portion corresponding to the folding area FA.

The digitizer 150 may include a body layer and/or a pattern layer. The digitizer 150 may detect a signal input from an external electronic pen or the like through the pattern layer. Particularly, the digitizer 150 may detect the intensity, direction, etc., of a signal input from an electronic pen or the like.

In a case where the digitizer 150 is integrally provided, the body layer and/or the pattern layer of the digitizer 150 may be cracked when the display apparatus 2000 is folded. In an embodiment, the digitizer 150 may include a first digitizer 150a positioned on a left side with respect to (or based on) the folding axis FAX and a second digitizer 150b positioned on a right side of the folding axis FAX. The first digitizer 150a may at least partially overlap the 2-1^{st} area A2a of FIG. 4, and the second digitizer 150b may at least partially overlap the 2-2^{nd} area A2b. In addition, the first digitizer 150a may at least partially overlap the folding area FA, and the second digitizer 150b may at least partially overlap the folding area FA.

In an embodiment, the first digitizer 150a and the second digitizer 150b may be apart from each other in the second direction DR2 with the folding axis FAX disposed therebetween. That is, the digitizer 150 may be provided as a separate type instead of an integral type. Because the digitizer 150 has a separate-type structure, cracks may be prevented or reduced from occurring in the body layer and/or the pattern layer arranged in the folding area FA.

In addition, because the digitizer 150 is provided as a separate type, and the digitizer 150 of a separate type at least partially overlaps the folding area FA, signals may be received even in the folding area FA, and thus, a user's convenience may be improved.

The heat dissipation member 160 may be disposed under the digitizer 150. The heat dissipation member 160 may be adhered to the digitizer 150 through an eighth adhesive layer 135. In an embodiment, the eighth adhesive layer 135 may not be provided at a portion corresponding to the folding area FA.

The heat dissipation member 160 may transfer heat generated from the digitizer 150 to the outside. In this case, the heat dissipation member 160 may include metal having high heat transfer efficiency. Alternatively, the heat dissipation member 160 may include graphite having high thermal conductivity in a planar direction. When the heat dissipation member 160 includes graphite, the heat dissipation member 160 may be relatively thin compared to when the heat dissipation member 160 includes metal. In addition, the heat dissipation member 160 may be disposed under the digitizer 150 to support the digitizer 150 and protect the digitizer 150 from external impact.

The heat dissipation member 160 may include a first heat dissipation member 160a positioned on a left side with respect to (or based on) the folding axis FAX and a second heat dissipation member 160b positioned on a right side of the folding axis FAX.

The cushion layer 170 may be disposed under the heat dissipation member 160. The cushion layer 170 may prevent or reduce the digitizer 150 disposed above the cushion layer 170 from being damaged due to external impact. In an embodiment, the cushion layer 170 may include a PSA.

The waterproof member 180 may be arranged on an outer side of the cushion layer 170. The waterproof member 180 may block or absorb moisture entering from the outside of the display apparatus 2000 and thus may prevent or reduce damage to elements of the display apparatus 2000 due to the moisture. In this regard, the waterproof member 180 may include a tape, a sponge, etc.

In an embodiment, the fifth adhesive layer 129, the support member 130, the sixth adhesive layer 131, the plate 140, the seventh adhesive layer 133, the digitizer 150, the eighth adhesive layer 135, the heat dissipation member 160, and the cushion layer 170 may include through holes 129H, 130H, 131H, 140H, 133H, 150H, 135H, 160H, and 170H corresponding to the first area A1, respectively. However, one or more embodiments are not limited thereto. At least one of the fifth adhesive layer 129, the support member 130, the sixth adhesive layer 131, the plate 140, the seventh adhesive layer 133, the digitizer 150, the eighth adhesive layer 135, the heat dissipation member 160, and the cushion layer 170 may not include a through hole. In addition, although not shown, a through hole may be additionally formed in the second protection member PB2.

In addition, FIG. 5 shows that the through holes 129H, 130H, 131H, 140H, 133H, 150H, 135H, 160H, and 170H corresponding to the first area A1 are provided on a left side of the display apparatus 2000, but one or more embodiments are not limited thereto. In an embodiment, the through holes 129H, 130H, 131H, 140H, 133H, 150H, 135H, 160H, and 170H corresponding to the first area A1 may be provided on a right side of the display apparatus 2000.

Because the fifth adhesive layer 129, the support member 130, the sixth adhesive layer 131, the plate 140, the seventh adhesive layer 133, the digitizer 150, the eighth adhesive layer 135, the heat dissipation member 160, and the cushion layer 170 include the through holes 129H, 130H, 131H, 140H, 133H, 150H, 135H, 160H, and 170H corresponding to the first area A1, respectively, light transmittance of the first area A1 may improve, thereby improving performance of the electronic module SS (refer to FIG. 2).

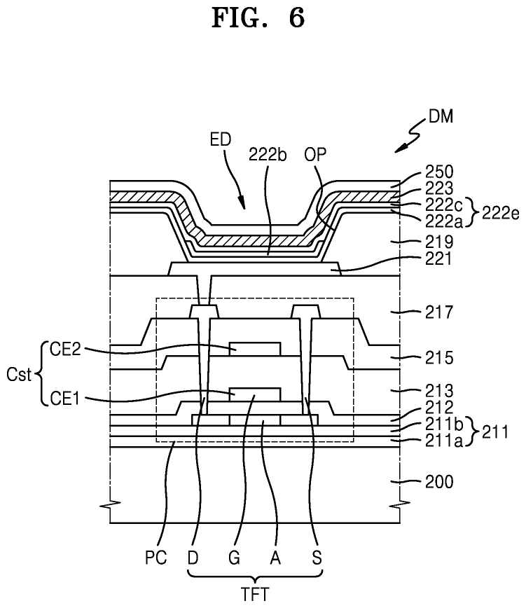

FIG. 6 is a schematic cross-sectional view of the display module DM of a display apparatus according to an embodiment.

Referring to FIG. 6, a substrate 200 may include an insulating material, such as glass, quartz, or polymer resin. The substrate 200 may be a rigid substrate or a flexible substrate which is bendable, foldable, or rollable.

In an embodiment, the substrate 200 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 200 may have a multi-layer structure including a layer including the above-described polymer resin and an inorganic layer (not shown). For example, the substrate 200 may include two layers including the above-described polymer resin and an inorganic barrier layer disposed therebetween.

A buffer layer 211 may be positioned on the substrate 200 to decrease or prevent the penetration of foreign materials, moisture, or external air from the bottom of the substrate 200 and may provide a flat surface on the substrate 200. The buffer layer 211 may include an inorganic material, such as oxide or nitride, an organic material, or an organic-inorganic compound, and may have a single-layer or multi-layer structure including an inorganic material and an organic material. A barrier layer (not shown) that prevents the penetration of external air may be further disposed between the substrate 200 and the buffer layer 211. In an embodiment, the buffer layer 211 may include silicon oxide (SiO₂) or silicon nitride (SiN_{X}). The buffer layer 211 may have a first buffer layer 211a and a second buffer layer 211b stacked on each other.

A pixel circuit PC including a thin-film transistor TFT and a storage capacitor Cst may be disposed on the buffer layer 211. In an embodiment, the thin-film transistor TFT may include a semiconductor layer A, a gate electrode G, a source electrode S, and a drain electrode D, and the storage capacitor Cst may include a bottom electrode CE1 and a top electrode CE2.

In an embodiment, the semiconductor layer A may be disposed on the buffer layer 211. In an embodiment, the semiconductor layer A may include polysilicon. Alternatively, in an embodiment, the semiconductor layer A may include amorphous silicon. In an embodiment, the semiconductor layer A may include oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer A may include a channel region and source and drain regions doped with impurities.

A first gate insulating layer 212 may be disposed over the semiconductor layer A. The first gate insulating layer 212 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The first gate insulating layer 212 may have a single-layer or multi-layer structure including the above-described inorganic insulating material.

The gate electrode G may be disposed on the first gate insulating layer 212. In an embodiment, the gate electrode G may at least partially overlap the semiconductor layer A disposed thereunder. In an embodiment, the gate electrode G may include molybdenum (Mo), aluminum (Al), copper (Cu), titanium (Ti), etc., and may include a single layer or a plurality of layers. For example, the gate electrode G may be a single molybdenum layer.

A second gate insulating layer 213 may be disposed over the gate electrode G. The second gate insulating layer 213 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The second gate insulating layer 213 may have a single-layer or multi-layer structure including the above-described inorganic insulating material.

The top electrode CE2 of the storage capacitor Cst may be disposed on the second gate insulating layer 213. In an embodiment, the top electrode CE2 may at least partially overlap the gate electrode G disposed thereunder. In an embodiment, the gate electrode G and the top electrode CE2 overlapping each other with the second gate insulating layer 213 disposed therebetween may constitute the storage capacitor Cst. For example, the gate electrode G may be the bottom electrode CE1 of the storage capacitor Cst.

The top electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

An interlayer insulating layer 215 may be disposed over the top electrode CE2. The interlayer insulating layer 215 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 215 may have a single-layer or multi-layer structure including the above-described inorganic insulating material.

The source electrode S and/or the drain electrode D may be disposed on the interlayer insulating layer 215. The source electrode S and/or the drain electrode D may include a conductive material including molybdenum (Mo), aluminum (Al), copper (Cu), titanium (Ti), etc., and may have a multi-layer or single-layer structure including the above-described material. In an embodiment, the source electrode S and the drain electrode D may have a multi-layer structure of titanium (Ti)/aluminum (Al)/titanium (Ti).

A planarization layer 217 may be disposed over the source electrode S and/or the drain electrode D. The planarization layer 217 may have a flat top surface such that a pixel electrode 221 disposed on the planarization layer 217 may be flat.

The planarization layer 217 may include an organic material or an inorganic material and may have a single-layer structure or a multi-layer structure. The planarization layer 217 may include a general commercial polymer, such as benzocyclobutene (BCB), polyimide, hexamethyldisiloxane (HMDSO), poly(methyl methacrylate) (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer. The planarization layer 217 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). When the inorganic material is used as the planarization layer 217, chemical and mechanical polishing may be performed on a top surface of the inorganic material layer to provide a flat top surface after the inorganic material layer is formed.

The planarization layer 217 may include a via hole exposing one of the source electrode S and/or the drain electrode D of the thin-film transistor TFT, and the pixel electrode 221 may be brought into contact with the source electrode S and/or the drain electrode D through the via hole and electrically connected to the thin-film transistor TFT.

In an embodiment, display elements including light-emitting elements ED may be disposed on the planarization layer 217. In an embodiment, the light-emitting elements ED may be organic light-emitting diodes (OLEDs). In an embodiment, an OLED may include the pixel electrode 221, an emission layer 222b, and an opposite electrode 223.

The pixel electrode 221 may be disposed on the planarization layer 217. The pixel electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 221 may have a structure including layers formed of ITO, IZO, ZnO, or In₂O₃ on/under the above-described reflective layer. In this case, the pixel electrode 221 may have a stack structure of ITO/Ag/ITO.

A pixel-defining layer 219 may cover edges of the pixel electrode 221 on the planarization layer 217 and may include an opening OP exposing at least a portion of the pixel electrode 221. An emission area of a light-emitting element ED, that is, the size and shape of a pixel, may be defined by the opening OP.

The pixel-defining layer 219 may prevent an arc, etc., from occurring at the edges of the pixel electrode 221 by increasing a distance between the edges of the pixel electrode 221 and the opposite electrode 223 disposed above the pixel electrode 221. The pixel-defining layer 219 may include an organic insulating material, such as polyimide, polyamide, acrylic resin, BCB, HMDSO, phenolic resin, etc., and may be formed by a method, such as spin coating.

The emission layer 222b may be arranged in the opening OP of the pixel-defining layer 219. The emission layer 222b may include a polymer material or a low-molecular weight material and may emit red, green, blue, or white light.

An organic functional layer 222e may be disposed on and/or under the emission layer 222b. The organic functional layer 222e may include a first functional layer 222a and/or a second functional layer 222c. However, at least one of the first functional layer 222a and the second functional layer 222c may be omitted.

The first functional layer 222a may be disposed under the emission layer 222b. The first functional layer 222a may have a single-layer or multi-layer structure including an organic material. The first functional layer 222a may be a hole transport layer (HTL) having a single-layer structure. Alternatively, the first functional layer 222a may include a hole injection layer (HIL) and an HTL. The first functional layer 222a may be integrally formed.

The second functional layer 222c may be disposed on the emission layer 222b. The second functional layer 222c may have a single-layer or multi-layer structure including an organic material. The second functional layer 222c may include an electron transport layer (ETL) and/or an electron injection layer (EIL). The second functional layer 222c may be integrally formed.

The opposite electrode 223 may be disposed on the second functional layer 222c. The opposite electrode 223 may include a conductive material having a low work function. For example, the opposite electrode 223 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 223 may further include a layer, such as ITO, IZO, ZnO, or In₂O₃, on a (semi)transparent layer including the above-described material. The opposite electrode 223 may be integrally formed.

A top layer 250 may be formed on the opposite electrode 223. In an embodiment, the top layer 250 may include an organic material or an inorganic material. The top layer 250 may protect the opposite electrode 223 and may also increase outcoupling efficiency. The top layer 250 may include an organic material having a higher refractive index than the opposite electrode 223. Alternatively, the top layer 250 may have layers of different refractive indices stacked on each other. For example, the top layer 250 may have a stack structure of a high refractive index layer/low refractive index layer/high refractive index layer. In this regard, a refractive index of the high refractive index layer may be about 1.7 or greater, and a refractive index of the low refractive index layer may be about 1.3 or less. However, one or more embodiments are not limited thereto.

The top layer 250 may additionally include lithium fluoride (LiF). Alternatively, the top layer 250 may additionally include an inorganic insulating material, such as silicon oxide (SiO₂) and/or silicon nitride (SiN_{X}). The top layer 250 may be omitted in some cases. However, a case where the top layer 250 is disposed on the opposite electrode 223 will be mainly described below for convenience.

Although not shown, an encapsulation member (not shown) may be disposed on the top layer 250. The encapsulation member may include an encapsulation substrate (not shown) opposite to the substrate 200 and a sealing member (not shown) disposed between the substrate 200 and the encapsulation substrate to block a space between the substrate 200 and the encapsulation substrate from the outside. Alternatively, the encapsulation member may include a thin-film encapsulation layer. The thin-film encapsulation layer may include at least one organic layer and at least one inorganic layer. For example, the thin-film encapsulation layer may include a first inorganic layer, a second inorganic layer, and an organic layer disposed between the first inorganic layer and the second inorganic layer.

The first inorganic layer may cover the opposite electrode 223 and may include silicon oxide, silicon nitride and/or silicon oxynitride. Because the first inorganic layer is formed along a structure thereunder, a top surface of the first inorganic layer may not be flat. The organic layer may cover the first inorganic layer, and, unlike the first inorganic layer, may have a substantially flat top surface. The organic layer may include one or more materials selected from the group consisting of polyethylene terephthalate, polyethylene naphthalate, polycarbonate, polyimide, polyethylene sulfonate, polyoxymethylene, polyarylate, and HMDSO. The second inorganic layer may cover the organic layer and may include silicon oxide, silicon nitride and/or silicon oxynitride.

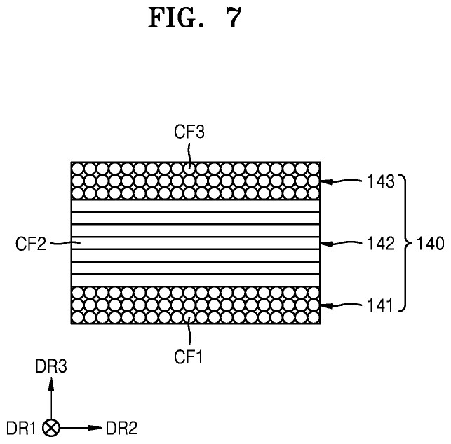

FIG. 7 is a schematic cross-sectional view of the plate 140 according to an embodiment.

Referring to FIG. 7, in an embodiment, the plate 140 may include carbon fiber reinforced plastic (CFRP). The plate 140 may include pitch-based carbon fiber. The plate 140 may include pitch-based carbon fiber and polyacrylonitrile (PAN)-based carbon fiber.

In an embodiment, the plate 140 may have a structure in which a plurality of layers are stacked on each other. For example, the plate 140 may include a first layer 141, a second layer 142, and a third layer 143. However, one or more embodiments are not limited thereto. The plate 140 may include two or four or more layers.

In an embodiment, the first layer 141 and the third layer 143 of the plate 140 may include the same material as each other, and the first layer 141 and the second layer 142 may include different materials from each other. That is, outermost layers on both sides of the plate 140 may include the same material as each other. For example, the first layer 141 and the third layer 143 may include PAN-based carbon fiber, and the second layer 142 may include pitch-based carbon fiber.

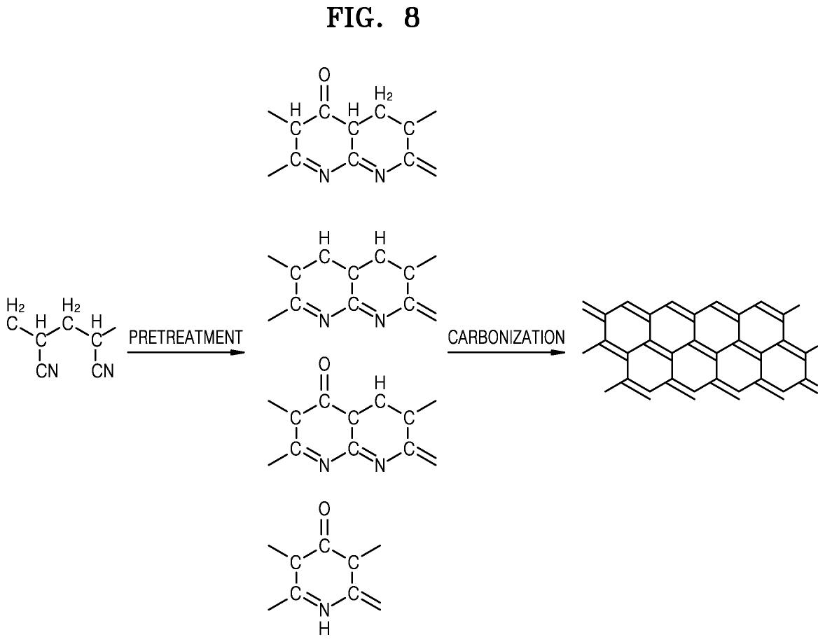

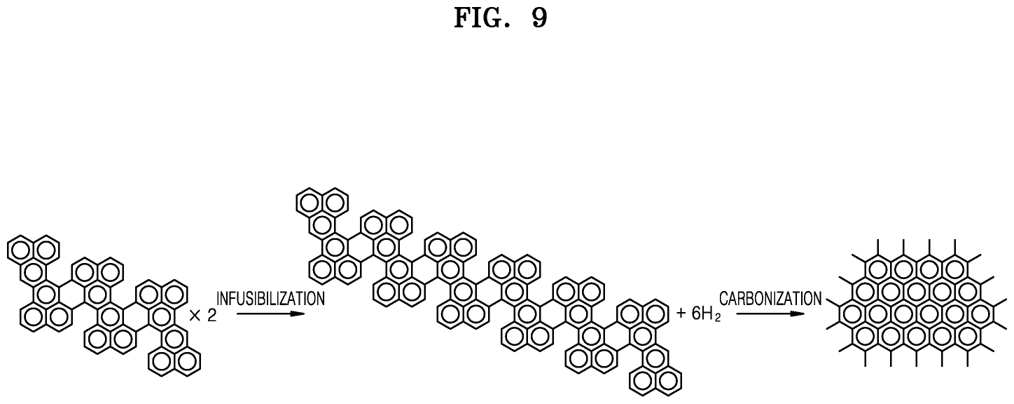

FIG. 8 is a schematic diagram of a method of manufacturing PAN-based carbon fiber. FIG. 9 is a schematic diagram of a method of manufacturing pitch-based carbon fiber.

Referring to FIG. 8, PAN-based carbon fiber may be manufactured through pretreatment and carbonization. More specifically, after PAN obtained by the polymerization and spinning of acrylonitrile is pre-treated at a temperature of 200° C. to 300° C. in air to manufacture pre-treated PAN having a ladder-type structure, the pre-treated PAN may be carbonized to manufacture PAN-based carbon fiber composed of condensed aromatic molecules.

In addition, referring to FIG. 9, after pitch is melt-spun and then infusibilized at a temperature of 200° C. to 350° C. in air to manufacture infusibilized pitch, the infusibilized pitch may be carbonized to manufacture pitch-based carbon fiber.

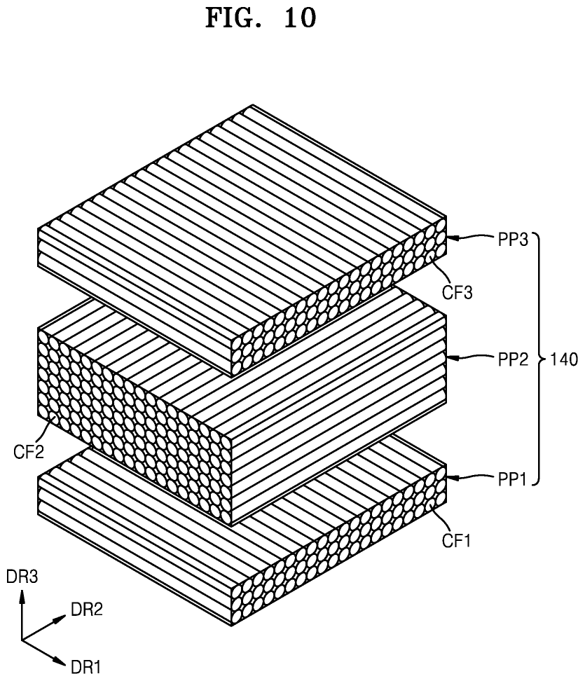

FIG. 10 is a schematic diagram of a process of manufacturing the plate 140, according to an embodiment.

Referring to FIG. 10, as described above, the plate 140 may have a structure in which a plurality of layers are stacked on each other. For example, the plate 140 may have a structure in which the first layer 141, the second layer 142, and the third layer 143 are stacked on one another. The plate 140 may be manufactured by heating and pressing a first prepreg PP1, a second prepreg PP2, and a third prepreg PP3.

In an embodiment, the first prepreg PP1 may include first carbon fibers CF1 and resin, the second prepreg PP2 may include second carbon fibers CF2 and resin, and the third prepreg PP3 may include third carbon fibers CF3 and resin. In this regard, the first carbon fibers CF1 and the third carbon fibers CF3 may be PAN-based carbon fiber, and the second carbon fibers CF2 may be pitch-based carbon fiber.

The first prepreg PP1 may be arranged such that the first carbon fibers CF1 included in the first prepreg PP1 extend in the first direction DR1. In other words, the first prepreg PP1 may be arranged such that a longitudinal direction of the first carbon fibers CF1 included in the first prepreg PP1 is parallel to the first direction DR1. In this regard, the first direction DR1 may be defined as a 0 degree direction.

After that, the second prepreg PP2 may be disposed on the first prepreg PP1. The second prepreg PP2 may be arranged such that the second carbon fibers CF2 included in the second prepreg PP2 extend in the second direction DR2 crossing the first direction DR1. In other words, the second prepreg PP2 may be arranged such that a longitudinal direction of the second carbon fibers CF2 included in the second prepreg PP2 is parallel to the second direction DR2 crossing the first direction DR1. In this regard, the second direction DR2 may be defined as a 90 degree direction. That is, the second prepreg PP2 may be rotated by 90 degrees to arrange the second prepreg PP2 such that the second carbon fibers CF2 included in the second prepreg PP2 extend in the second direction DR2 crossing the first direction DR1.

In addition, the third prepreg PP3 may be disposed on the second prepreg PP2. The third prepreg PP3 may be arranged such that the third carbon fibers CF3 included in the third prepreg PP3 extend in the first direction DR1. In other words, the third prepreg PP3 may be arranged such that a longitudinal direction of the third carbon fibers CF3 included in the third prepreg PP3 is parallel to the first direction DR1.

Accordingly, the first carbon fibers CF1 included in the first prepreg PP1 and the second carbon fibers CF2 included in the second prepreg PP2 may cross each other to form 90 degrees, and the second carbon fibers CF2 included in the second prepreg PP2 and the third carbon fibers CF3 included in the third prepreg PP3 may be arranged to cross each other to form 90 degrees.

The first prepreg PP1, the second prepreg PP2, and the third prepreg PP3 may be arranged and then may be hot pressed in an elevated temperature. For example, the first prepreg PP1, the second prepreg PP2, and the third prepreg PP3 may be stacked and hot pressed in the elevated temperature using a hot press or an autoclave.

Referring to FIGS. 7 and 10, the plate 140 including the first layer 141, the second layer 142, and the third layer 143 may be formed by hot pressing the stack of the first prepreg PP1, the second prepreg PP2, and the third prepreg PP3 in the elevated temperature. The first layer 141 of the plate 140 may correspond to the first prepreg PP1, the second layer 142 of the plate 140 may correspond to the second prepreg PP2, and the third layer 143 of the plate 140 may correspond to the third prepreg PP3. For example, the first layer 141, the second layer 142, and the third layer 143 may be a hot pressed first prepreg PP1, a hot pressed second prepreg PP2, and a hot pressed third prepreg PP3, respectively.

In an embodiment, the first layer 141 of the plate 140 may include CFRP. The first layer 141 may include CFRP hardened by impregnating the first carbon fibers CF1 with resin. The first carbon fibers CF1 of the first layer 141 may extend in the first direction DR1. In other words, a longitudinal direction of the first carbon fibers CF1 of the first layer 141 may be parallel to the first direction DR1. The longitudinal direction of the first carbon fibers CF1 of the first layer 141 may be parallel to a direction in which the folding axis FAX extends.

In an embodiment, the first layer 141 may include PAN-based carbon fiber. The first carbon fibers CF1 included in the first layer 141 may be PAN-based carbon fiber. A fiber area weight (FAW) of the first layer 141 may be greater than or equal to 20 g/m² and less than or equal to 30 g/m². When a FAW of the first layer 141 is less than 20 g/m², strength of the plate 140 including the first layer 141 is too low, and thus, the display module DM (refer to FIG. 5) and/or the digitizer 150 (refer to FIG. 5) may be damaged due to external impact. On the other hand, when a FAW of the first layer 141 is greater than 30 g/m², a step difference of fiber may be visible, and thus, surface quality may be degraded. Accordingly, when a FAW of the first layer 141 is equal to or greater than 20 g/m² and less than or equal to 30 g/m², the plate 140 may have the strength of a certain level or greater, and degradation of surface quality due to the visibility of a step difference of fiber may be prevented.

In an embodiment, the second layer 142 of the plate 140 may include CFRP. The second layer 142 may include CFRP hardened by impregnating the second carbon fibers CF2 with resin. The second carbon fibers CF2 of the second layer 142 may extend in the second direction DR2. In other words, a longitudinal direction of the second carbon fibers CF2 of the second layer 142 may be parallel to the second direction DR2. The longitudinal direction of the second carbon fibers CF2 of the second layer 142 may be perpendicular to the direction in which the folding axis FAX extends.

In an embodiment, the second layer 142 may include a material different from that of the first layer 141. The second layer 142 may include pitch-based carbon fiber. The second carbon fibers CF2 included in the second layer 142 may be pitch-based carbon fiber. A FAW of the second layer 142 may be greater than or equal to 50 g/m² and less than or equal to 150 g/m². When a FAW of the second layer 142 is less than 50 g/m², a difference between a machine direction (MD) modulus and a transverse direction (TD) modulus of the plate 140 may increase, and the MD modulus of the plate 140 may be too small. On the other hand, when a FAW of the second layer 142 is greater than 150 g/m², the plate 140 including the second layer 142 may be too thick, and the display apparatus 2000 (refer to FIG. 5) including the plate 140 may be too thick. Accordingly, because a FAW of the second layer 142 is greater than or equal to 50 g/m² and less than or equal to 150 g/m², a difference between an MD modulus and a TD modulus of the plate 140 may be reduced, and the plate 140 and/or the display apparatus 2000 may be prevented from becoming thicker.

In an embodiment, the third layer 143 of the plate 140 may include CFRP. The third layer 143 may include CFRP hardened by impregnating the third carbon fibers CF3 with resin. The third carbon fibers CF3 of the third layer 143 may extend in the first direction DR1. In other words, a longitudinal direction of the third carbon fibers CF3 of the third layer 143 may be parallel to the first direction DR1. The longitudinal direction of the third carbon fibers CF3 of the third layer 143 may be parallel to the direction in which the folding axis FAX extends.

In an embodiment, the third layer 143 may include the same material as the first layer 141. The third layer 143 may include a material different from that of the second layer 142. The third layer 143 may include PAN-based carbon fiber. The third carbon fibers CF3 included in the third layer 143 may be PAN-based carbon fiber. A FAW of the third layer 143 may be greater than or equal to 20 g/m² and less than or equal to 30 g/m². When a FAW of the third layer 143 is less than 20 g/m², strength of the plate 140 including the third layer 143 is too low, and thus, the display module DM (refer to FIG. 5) and/or the digitizer 150 (refer to FIG. 5) may be damaged due to external impact. On the other hand, when a FAW of the third layer 143 is greater than 30 g/m², a step difference of fiber may be visible, and thus, surface quality may be degraded. Accordingly, because a FAW of the third layer 143 is greater than or equal to 20 g/m² and less than or equal to 30 g/m², the plate 140 may have the strength of a certain level or greater, and degradation of surface quality due to the visibility of a step difference of fiber may be prevented.

In an embodiment, a ratio (%) of a TD modulus to an MD modulus of the plate 140 may be about 50% or greater and about 150% or less. The ratio (%) of a TD modulus to an MD modulus of the plate 140 may be about 50% or greater and about 140% or less. The ratio (%) of a TD modulus to an MD modulus of the plate 140 may be about 60% or greater and about 150% or less. The ratio (%) of a TD modulus to an MD modulus of the plate 140 may be about 60% or greater and about 140% or less. The ratio (%) of a TD modulus to an MD modulus of the plate 140 may be about 70% or greater and about 150% or less. The ratio (%) of a TD modulus to an MD modulus of the plate 140 may be about 70% or greater and about 140% or less. The ratio (%) of a TD modulus to an MD modulus of the plate 140 may be about 80% or greater and about 150% or less. Alternatively, the ratio (%) of a TD modulus to an MD modulus of the plate 140 may be about 80% or greater and about 140% or less. In this regard, the TD may be a direction parallel to the first direction DR1, and the MD may be a direction parallel to the second direction DR2. That is, the TD and the first direction DR1 may be the same direction as each other, and the MD and the second direction DR2 may be the same direction as each other.

In an embodiment, when a ball drop test of the plate 140 is performed, a ball drop height may be 10 cm or greater.

### Experimental Example

Hereinafter, one or more embodiments will be described in more detail through an experimental example. However, the following experimental example is intended to describe one or more embodiments in more detail, and the scope of one or more embodiments is not limited by the following experimental example. The following experimental example may be appropriately modified or changed by those skilled in the art without departing from the scope of one or more embodiments.

Table 1 shows three-point bending test evaluation results of Embodiments 1 to 3 and Comparative Examples 1 to 4, ball drop test results of Embodiments 1 to 3 and Comparative Examples 1 to 4, and evaluation results of Embodiments 1 to 3 and Comparative Examples 1 to 4 regarding whether a step difference of fiber is visible to the naked eye.

TABLE 1

| | | | | | | Whether or not a |
|---|---|---|---|---|---|---|
| | | | | | | step difference |
| | | | | | Ball drop | of fiber is |
| | | | | | test defect | visible to the |
| | | TD | MD | TD/MD | occurrence | naked eye |
| | Thickness | modulus | modulus | ratio | height | (Degradation of |
| | (mm) | (GPa) | (GPa) | (%) | (cm) | surface quality) |
| Embodiment 1 | 0.175 | 54 | 49 | 110 | 11 | X |
| Embodiment 2 | 0.190 | 70 | 51 | 137 | 11 | X |
| Embodiment 3 | 0.199 | 62 | 68 | 91 | 13 | X |
| Comparative | 0.176 | 52 | 26 | 200 | 6 | X |
| example 1 | | | | | | |
| Comparative | 0.192 | 68 | 25 | 272 | 6 | X |
| example 2 | | | | | | |
| Comparative | 0.198 | 59 | 37 | 159 | 6.5 | X |
| example 3 | | | | | | |
| Comparative | 0.199 | 91 | 45 | 202 | 15 | ◯ |
| example 4 | | | | | | |

Embodiment 1 corresponds to a case where a first layer and a third layer include PAN-based carbon fiber, a second layer includes pitch-based carbon fiber, a FAW of each of the first layer and the third layer is 22 g/m², and a FAW of the second layer is 125 g/m².

Embodiment 2 corresponds to a case where a first layer and a third layer include PAN-based carbon fiber, a second layer includes pitch-based carbon fiber, a FAW of each of the first layer and the third layer is 30 g/m², and a FAW of the second layer is 125 g/m².

Embodiment 3 corresponds to a case where a first layer and a third layer include PAN-based carbon fiber, a second layer includes pitch-based carbon fiber, a FAW of each of the first layer and the third layer is 22 g/m², and a FAW of the second layer is 150 g/m².

Comparative example 1 corresponds to a case where all of a first layer, a second layer, and a third layer include PAN-based carbon fiber, a FAW of each of the first layer and the third layer is 22 g/m², and a FAW of the second layer is 125 g/m².

Comparative example 2 corresponds to a case where all of a first layer, a second layer, and a third layer include PAN-based carbon fiber, a FAW of each of the first layer and the third layer is 30 g/m², and a FAW of the second layer is 125 g/m².

Comparative example 3 corresponds to a case where all of a first layer, a second layer, and a third layer include PAN-based carbon fiber, a FAW of each of the first layer and the third layer is 22 g/m², and a FAW of the second layer is 150 g/m².

Comparative example 4 corresponds to a case where all of a first layer, a second layer, and a third layer include pitch-based carbon fiber, a FAW of each of the first layer and the third layer is 50 g/m², and a FAW of the second layer is 100 g/m².

The TD modulus and the MD modulus were measured through a three-point bending test according to ASTM D638 conditions. In this regard, the TD may be a direction parallel to the first direction DR1, and the MD may be a direction parallel to the second direction DR2.

To obtain the ball drop test results, a height (cm) at which a plate is destroyed when a 58-g steel ball is dropped was measured.

Referring to Comparative example 1, when all of the first layer, the second layer, and the third layer include PAN-based carbon fiber, it may be confirmed that a difference between the TD modulus and the MD modulus is considerable and the MD modulus has a low value. It may also be confirmed that, as a result of the ball drop test, a defect occurs at a low height (e.g., 6 cm).

Referring to Comparative example 2, when the FAW of each of the first layer and the third layer is increased compared to Comparative example 1, it may be confirmed that the TD modulus increases and thus a difference between the TD modulus and the MD modulus increases. It may also be confirmed that the MD modulus has a low value, and as a result of the ball drop test, a defect occurs at a low height (e.g., 6 cm).

Referring to Comparative example 3, when the FAW of the second layer is increased compared to Comparative example 1, it may be confirmed that, although both of the TD modulus and the MD modulus are increased compared to Comparative example 1, a difference between the TD modulus and the MD modulus is still considerable and the MD modulus has a low value. It may also be confirmed that, as a result of the ball drop test, a defect occurs at a low height (e.g., 6.5 cm).

Referring to Comparative example 4, when all of the first layer, the second layer, and the third layer include pitch-based carbon fiber, it may be confirmed that, although the MD modulus is increased compared to the other comparative examples, a difference between the TD modulus and the MD modulus is still considerable. It may also be confirmed that, when the FAW of each of the first layer and the third layer is greater than 30 g/m², a step difference of fiber is visible to the naked eye. When the step difference of fiber is visible to the naked eye, surface quality may be degraded.

Referring to Embodiment 1, when the first layer and the third layer include PAN-based carbon fiber, the second layer includes pitch-based carbon fiber, and FAWs of the first layer, the second layer, and the third layer satisfy required conditions, it may be confirmed that a difference between the TD modulus and the MD modulus is reduced compared to Comparative examples 1 to 4. In addition, it may be confirmed that the MD modulus is increased compared to Comparative examples 1 to 4, and as a result of the ball drop test, a defect occurs at a high height (e.g., 11 cm) and therefore it may be confirmed that Embodiment 1 has excellent resistance to impact compared to the comparative examples.

Referring to Embodiment 2, when the FAW of each of the first layer and the third layer is increased compared to Embodiment 1, it may be confirmed that the TD modulus and the MD modulus increase. In this regard, it may be confirmed that the MD modulus has a smaller increase than the TD modulus. In addition, in Embodiment 2, it may be confirmed that a difference between the TD modulus and the MD modulus is small compared to Comparative examples 1 to 4. In addition, as a result of the ball drop test, a defect occurs at a high height (e.g., 11 cm), and therefore, it may be confirmed that Embodiment 2 has excellent resistance to impact compared to Comparative examples 1 to 4.

Referring to Embodiment 3, when the FAW of the second layer is increased compared to Embodiment 1, it may be confirmed that the TD modulus and the MD modulus increase. In this regard, it may be confirmed that an increase in the MD modulus is greater than an increase in the TD modulus. In addition, in Embodiment 3, it may be confirmed that a difference between the TD modulus and the MD modulus is small compared to Comparative examples 1 to 4. As a result of the ball drop test, a defect occurs at a high height (e.g., 13 cm), and therefore, it may be confirmed that impact resistance of Embodiment 3 is excellent compared to impact resistance of Comparative examples 1 to 4.

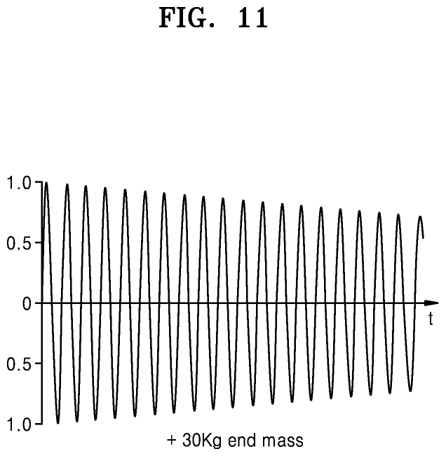

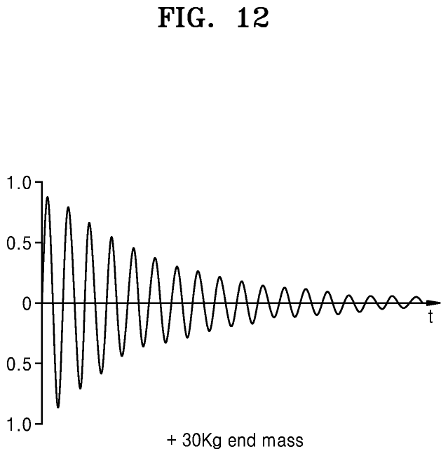

FIGS. 11 and 12 are diagrams showing evaluation results of vibration damping characteristics of CFRP including PAN-based carbon fiber and CFRP including pitch-based carbon fiber, respectively. FIGS. 11 and 12 are graphs showing the degree of vibration damping over time (t) for CFRP including PAN-based carbon fiber and CFRP including pitch-based carbon fiber, respectively.

Referring to FIGS. 11 and 12, when the evaluation of vibration damping characteristics is performed on CFRP including PAN-based carbon fiber and CFRP including pitch-based carbon fiber under the same conditions, it may be confirmed that vibration damping properties of CFRP including pitch-based carbon fiber are excellent compared to vibration damping properties of CFRP including PAN-based carbon fiber. That is, it may be confirmed that CFRP including pitch-based carbon fiber absorbs vibration better than CFRP including PAN-based carbon fiber.

Accordingly, when a second layer includes pitch-based carbon fiber, vibration damping characteristics of a plate may be improved, and thus, impact resistance of the plate may be improved.

When the plate 140 includes the first layer 141, the second layer 142, and the third layer 143, and all of the first layer 141, the second layer 142, and the third layer 143 include PAN-based carbon fiber, a difference between a TD modulus and an MD modulus may be considerable, and the MD modulus may have a low value. In addition, the plate 140 and/or a display apparatus may have poor resistance to impact due to poor vibration damping characteristics.

On the other hand, in an embodiment, when the plate 140 includes the first layer 141, the second layer 142, and the third layer 143, the first layer 141 and the third layer 143 include PAN-based carbon fiber, and the second layer 142 includes pitch-based carbon fiber, a difference between a TD modulus and an MD modulus may be reduced, and the MD modulus may be increased. In addition, vibration damping characteristics of pitch-based carbon fiber are excellent, and therefore, when the second layer 142 includes pitch-based carbon fiber, impact resistance of the plate 140 may be improved. Further, when FAWs of the first layer 141, the second layer 142, and the third layer 143 satisfy previously set conditions, a step difference of fiber may be prevented from being visible to the naked eye, and thus, degradation of surface quality may be prevented.

According to one or more of the above embodiments, a display apparatus in which a plate includes PAN-based carbon fiber and pitch-based carbon fiber and thus a difference between moduli according to directions is reduced may be provided. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display module; and
a plate arranged below the display module and comprising pitch-based carbon fiber.

2. The display apparatus of claim 1, wherein the plate further comprises polyacrylonitrile (PAN)-based carbon fiber.

3. The display apparatus of claim 1, wherein the plate comprises a plurality of layers.

4. The display apparatus of claim 3, wherein an outermost layer of the plate comprises PAN-based carbon fiber and an inner layer comprises pitch-based carbon fiber.

5. The display apparatus of claim 1, wherein the plate comprises a first layer, a second layer, and a third layer that are sequentially stacked on one another.

6. The display apparatus of claim 5, wherein the first layer and the third layer comprise a same carbon fiber.

7. The display apparatus of claim 5, wherein the first layer and the second layer comprise different carbon fibers.

8. The display apparatus of claim 5, wherein the first layer and the third layer comprise PAN-based carbon fiber.

9. The display apparatus of claim 8, wherein the second layer comprises pitch-based carbon fiber.

10. The display apparatus of claim 9, wherein a fiber area weight (FAW) of the first layer is greater than or equal to 20 g/m² and less than or equal to 30 g/m².

11. The display apparatus of claim 9, wherein a FAW of the third layer is greater than or equal to 20 g/m² and less than or equal to 30 g/m².

12. The display apparatus of claim 9, wherein a FAW of the second layer is greater than or equal to 50 g/m² and less than or equal to 150 g/m².

13. The display apparatus of claim 9, wherein a longitudinal direction of the carbon fiber included in the first layer is parallel to a first direction.

14. The display apparatus of claim 13, wherein a longitudinal direction of the carbon fiber included in the second layer is parallel to a second direction crossing the first direction.

15. The display apparatus of claim 13, wherein a longitudinal direction of the carbon fiber included in the third layer is parallel to the first direction.

16. The display apparatus of claim 1, further comprising a digitizer arranged under the plate.

17. A display apparatus comprising:
a display module comprising a first area, a second area, and a folding area, and being foldable with respect to a folding axis; and
a plate arranged below the display module and comprising pitch-based carbon fiber.

18. The display apparatus of claim 17, wherein the second area comprises a 2-1^{st} area and a 2-2^{nd} area.

19. The display apparatus of claim 18, wherein the folding area is disposed between the 2-1^{st} area and the 2-2^{nd} area.

20. The display apparatus of claim 17, wherein the plate further comprises polyacrylonitrile (PAN)-based carbon fiber.

21. The display apparatus of claim 17, wherein the folding axis extends in a first direction.

22. The display apparatus of claim 21, wherein the plate comprises a first layer, a second layer, and a third layer that are sequentially stacked on one another.

23. The display apparatus of claim 22, wherein the first layer and the third layer comprise PAN-based carbon fiber.

24. The display apparatus of claim 23, wherein the second layer comprises the pitch-based carbon fiber.

25. The display apparatus of claim 24, wherein a fiber area weight (FAW) of each of the first layer and the third layer is greater than or equal to 20 g/m² and less than or equal to 30 g/m².

26. The display apparatus of claim 25, wherein a FAW of the second layer is greater than or equal to 50 g/m² and less than or equal to 150 g/m².

27. The display apparatus of claim 22, wherein a longitudinal direction of a carbon fiber included in the first layer is parallel to the first direction.

28. The display apparatus of claim 27, wherein a longitudinal direction of a carbon fiber included in the second layer is parallel to a second direction crossing the first direction.

29. The display apparatus of claim 28, wherein a longitudinal direction of a carbon fiber included in the third layer is parallel to the first direction.

30. The display apparatus of claim 17, further comprising a digitizer arranged under the plate.
